(19) United States
(12) Patent Application Publication
(10) Pub. No.: US 2006/0007029 A1
(43) Pub. Date: Jan. 12, 2006

(54) D/A conversion apparatus with offset compensation function and offset compensation method for a D/A conversion apparatus

(75) Inventor: Minoru Ito, Shiga (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/175,132

(22) Filed: Jul. 7, 2005

(30) Foreign Application Priority Data
Jul. 9, 2004 (JP) 2004-203794

(51) Int. Cl. H03M 1/66

(52) U.S. Cl. 341/144

(57) ABSTRACT

It is an object of the present invention to enable a DC offset of a D/A converter to be removed substantially completely even when a DC offset exists in a comparator. An input switchover switch 160 is provided between complementary outputs A+, A− of a D/A converter 130 and an input of a comparator 150. An input signal correction section 110 calculates a zero-cross delay value when an output A+ of the D/A converter 130 and a + input of the comparator 150 are connected and an output A− of the D/A converter 130 and a − input of the comparator 150 are connected, and a zero-cross delay value when the output A+ of the D/A converter 130 and the − input of the comparator 150 are connected and the output A− of the D/A converter 130 and the + input of the comparator 150 are connected, adds up the two zero-cross delay values calculated, decides whether the value is positive, negative or zero, integrates the result and uses a DC offset compensation value generated to thereby correct a digital input signal using an adder 128.

### BACKGROUND OF THE INVENTION

1. Field of the Invention

The present invention relates to a D/A conversion apparatus with an offset compensation function and an offset compensation method for a D/A conversion apparatus, and more particularly, to an apparatus and method for compensating a DC offset of a D/A converter incorporated in a digital radio communication instrument.

2. Description of the Related Art

A digital radio communication instrument D/A-converts digital-modulated I (in-phase) and Q (quadrature-phase) signals, combines them into a radio frequency section of a radio telephone and sends the combined signal as a radio signal to an antenna. It would be ideal that an analog output voltage of a D/A converter match an ideal analog output voltage (analog output voltage with no DC offset) corresponding to a digital input value, but a DC offset is actually produced between the actual output and ideal output for various causes.

In the case of a differential output type D/A converter, a DC offset is produced between differential outputs (I+ and I− or Q+ and Q−) of the D/A converter corresponding to each of an I signal and a Q signal. That is, there is a difference in the input/output characteristic between the differential outputs of the D/A converter. When a DC offset is produced in each of the I signal and Q signal, a phase shift is produced between the I, Q signals, resulting in a transmission error.

In order to eliminate such a transmission error, it is necessary to cancel the DC offset between the differential outputs of the D/A converter so as to make the characteristic of the D/A converter uniform.

As a method for canceling a DC offset between differential outputs of a D/A converter in normal operation having a signal to be sent to a radio path, a conventional method is known which measures a time difference between the times required for a digital input signal of the D/A converter and an analog output signal of the D/A converter which has passed through a lowpass filter to cross a reference voltage (0 V) (hereinafter referred to as “zero-cross delay value”) (e.g., WO00/01073 pamphlet).

That is, when there is no DC offset in the D/A converter, a zero-cross delay value during a signal rise time becomes equal to a zero-cross delay value during a signal fall time, whereas when there is a DC offset in the D/A converter, a difference is produced between a zero-cross delay value during a signal rise time and a zero-cross delay value during a signal fall time. Thus, a comparator (voltage comparator) is connected to the differential outputs of the D/A converter, the result {+1, −1} of a voltage comparison by the comparator and the result {+1, 0, −1} of deciding the MSB {+1, −1} of the digital input signal of the D/A converter are integrated using a clock signal, zero-cross delay values during a signal rise time and a signal fall time are calculated, the digital input signal is corrected according to the difference between the zero-cross delay values obtained, and the DC offset between the differential outputs of the D/A converter is thereby cancelled.

However, the conventional method gives no consideration to the DC offset of the comparator itself and there is a certain limit on the removal of the DC offset of the D/A converter.

That is, the DC offset actually exists not only in the comparator which detects a DC offset of the single output type D/A conversion apparatus but also in the comparator which detects a DC offset between the differential outputs of the differential output type D/A conversion apparatus. The DC offset of the comparator is normally designed to fall within a range of several mV.

However, the result of an investigation by the present inventor has confirmed that the DC offset of the comparator itself may exceed 20 mV due to variations in the transistor size and LSI manufacturing process conditions, etc. As the transistors are miniaturized in particular, the DC offset of the comparator tends to increase.

The DC offset of the comparator becomes an error when the DC offset (including a DC offset between differential outputs) is measured. Therefore, when the DC offset of the comparator itself is large, it is not possible to carry out accurate measurement or completely remove the DC offset of the D/A converter.

### SUMMARY OF THE INVENTION

It is an object of the present invention to provide a D/A conversion apparatus with an offset compensation function and an offset compensation method for a D/A conversion apparatus capable of removing a DC offset of the D/A converter substantially completely even when a DC offset exists in a comparator.

According to an aspect of the invention, a D/A conversion apparatus with an offset compensation function, that compensates for a DC offset of a D/A converter, has a comparator provided with two input terminals that inputs an output signal of the D/A converter to at least one of the input terminals, a switchover section that switches between a pair of signals which are input to the comparator during normal operation of transmitting a transmission signal, at least one of which is an output signal of the D/A converter, a zero-cross delay value generation section that measures and adds up zero-cross delay values during a rise time and during a fall time of the output signals of the D/A converter before and after switching between the pair of signals to be input to the comparator respectively to thereby generate a first zero-cross delay value before switching between the pair of signals to be input to the comparator and a second zero-cross delay value after switching between the pair of signals to be input to the comparator, a compensation value generation section that generates a compensation value of the DC offset using the first zero-cross delay value and the second zero-cross delay value and a correction section that corrects a digital input signal to the D/A converter using the compensation value.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a block diagram showing the configuration of a D/A conversion apparatus with an offset compensation function according to Embodiment 1 of the present invention;

FIG. 2 illustrates the operation (generation operation of a first zero-cross delay value) of the D/A conversion apparatus corresponding to Embodiment 1;

FIG. 3 illustrates the operation (generation operation of a second zero-cross delay value and generation operation of a DC offset compensation value) of the D/A conversion apparatus corresponding to Embodiment 1;

FIG. 4 illustrates waveforms of (A+)-(A−) when there is no DC offset in the comparator;

FIG. 5 illustrates waveforms of (A+)-(A−) when there is a DC offset in the comparator and in a first switch state (first input mode);

FIG. 6 illustrates waveforms of (A+)-(A−) when there is a DC offset in the comparator and in a second switch state (second input mode);

FIG. 7 is a block diagram showing the configuration of a D/A conversion apparatus with an offset compensation function according to Embodiment 2 of the present invention;

FIG. 8 is a block diagram showing the configuration of a D/A conversion apparatus with an offset compensation function according to Embodiment 3 of the present invention;

FIG. 9 is a block diagram showing the configuration of a D/A conversion apparatus with an offset compensation function according to Embodiment 4 of the present invention; and

FIG. 10 is a block diagram showing an example of the configuration of a digital radio transmitter provided with the D/A conversion apparatus with an offset compensation function of the present invention.

### DETAILED DESCRIPTION OF THE PREFERRED EMBODIMENTS

When a DC offset of a D/A converter is measured, the present invention switches between a pair of signals to be input to a comparator, calculates zero-cross delay values during a rise time and during a fall time of the respective signals, calculates a zero-cross delay value obtained by adding up the zero-cross delay values before and after the above described switchover taking advantage of the fact that the delay value corresponding to the DC offset of the comparator having different polarities itself is added to the zero-cross delay values before and after the above described switchover, and can thereby cancel out the DC offset of the comparator itself. This allows accurate measurement of the DC offset of the D/A converter.

According to an aspect of the D/A conversion apparatus with an offset compensation function of the present invention, the apparatus has a switchover section provided with two input terminals of the comparator (inversion terminal and non-inversion terminal) that switches between a pair of signals, at least one of which is an output signal of the D/A converter and a polarity inversion section that selectively inverts the polarity of the output signal of the comparator, switches between signals to be input to the comparator, measures zero-cross delay values during a rise time and a fall time of the output signals of the D/A converter respectively to generate first and second zero-cross delay values, adds up those delay values, decides whether the value is positive, negative or zero, integrates the decision result and thereby generates a DC offset compensation value. Then, the digital input signal is corrected by an adder using the compensation value.

That is, when signals to be input to the comparator are switched over, in the case of the first zero-cross delay value measured before the switchover, for example, the delay value corresponding to the DC offset of the comparator itself acts in the direction in which the zero-cross delay values of the two signals are expanded, whereas in the case of the second zero-cross delay value measured after the switchover, the delay value acts in the direction in which the zero-cross delay values of the two signals are reduced. That is, the polarity of the delay value corresponding to the DC offset of the comparator itself is reversed before and after the switchover.

On the other hand, the zero-cross delay value corresponding to the DC offset of the D/A converter remains the same (the polarity also remains the same) irrespective of the switchover of inputs to the comparator.

Therefore, when the first and second zero-cross delay values generated based on the measurement signals before and after the switchover of inputs to the comparator are added, the delay values corresponding to the DC offset of the comparator itself are substantially canceled out and disappear. Therefore, it is possible to calculate a precise compensation value corresponding to the net DC offset of the D/A converter deprived of the DC offset of the comparator by integrating based on the decision result {+1, 0, −1} obtained from the acquired zero-cross delay value and thereby generating the DC offset compensation value.

The present invention is applicable irrespective of whether the D/A converter is of a differential output type (complementary output type for expanding the dynamic range of conversion output) or a single output type. Furthermore, various methods of converting the first and second zero-cross delay values to DC offset compensation values will be explained in their respective embodiments.

The present invention generates a compensation value by taking into consideration a DC offset of the comparator itself and a DC offset of the D/A converter and provides a digital input signal of the D/A converter with negative feedback, and therefore the DC offset of comparator seems transparent to the D/A conversion apparatus as a whole. That is, this substantially means that the DC offset of the D/A conversion apparatus is measured by the comparator free of the DC offset.

According to the present invention, it is possible to remove the DC offset of the comparator itself and the DC offset of the D/A converter simultaneously and substantially completely. Furthermore, the present invention has a simple configuration and the control method thereof is also simple, and therefore the present invention can be easily implemented. Furthermore, miniaturizing the analog circuit will further increase the DC offset of the comparator. Therefore, the present invention is very effective as the means for realizing the D/A conversion apparatus substantially completely free of the DC offset using a miniaturization process.

With reference now to the attached drawings, embodiments of the present invention will be explained in detail below. The following explanations are not intended to limit the scope of the present invention.

### Embodiment 1

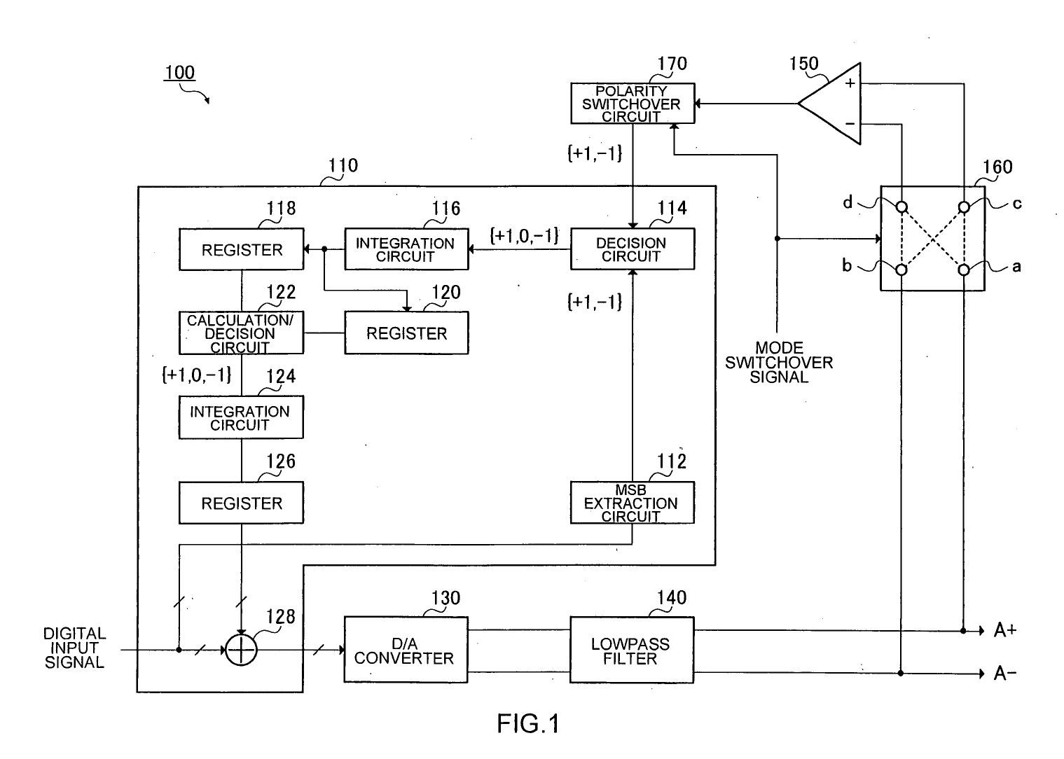

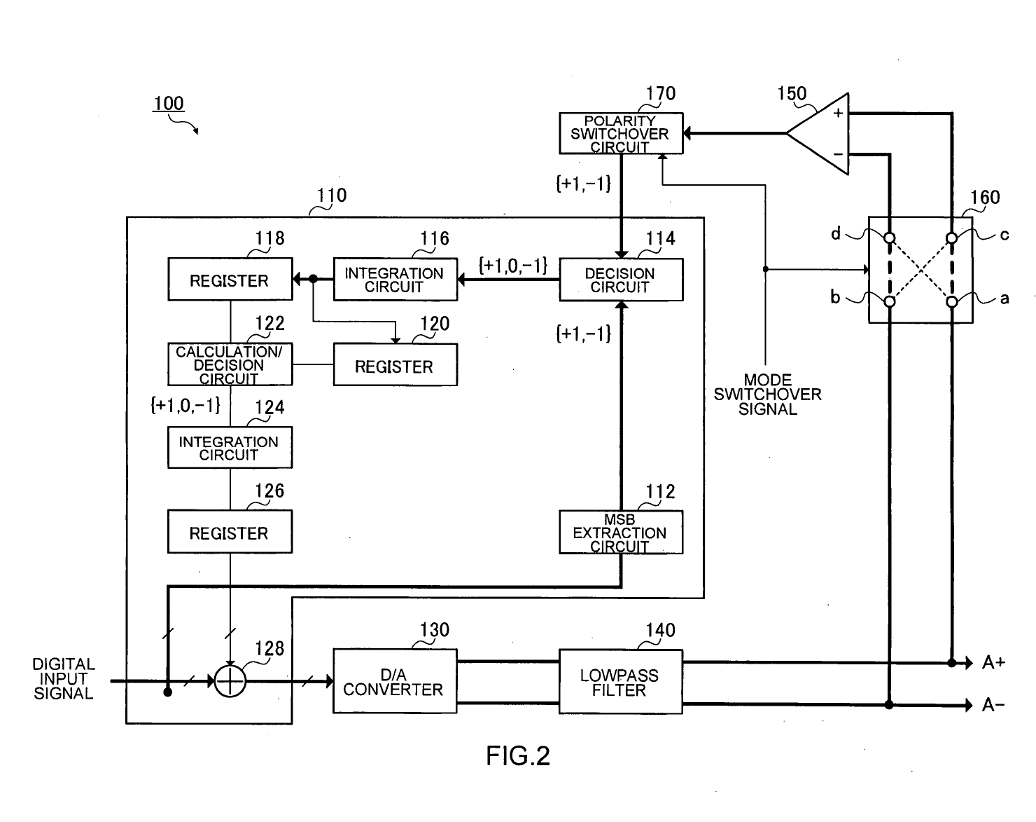

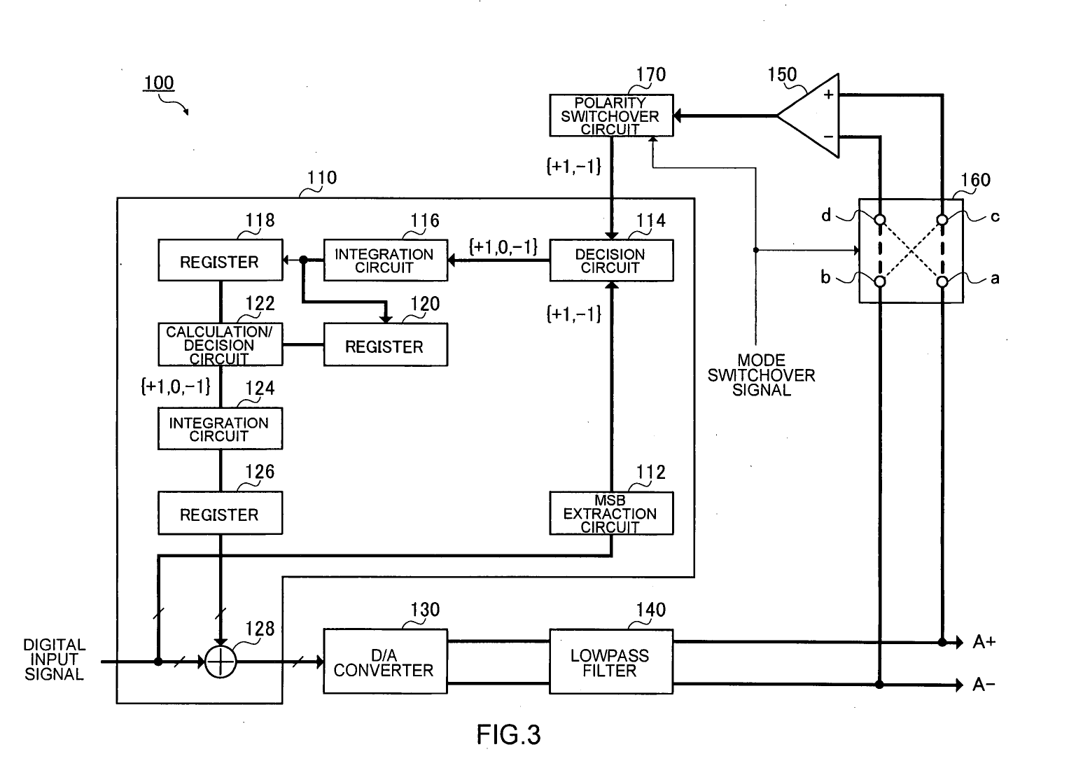

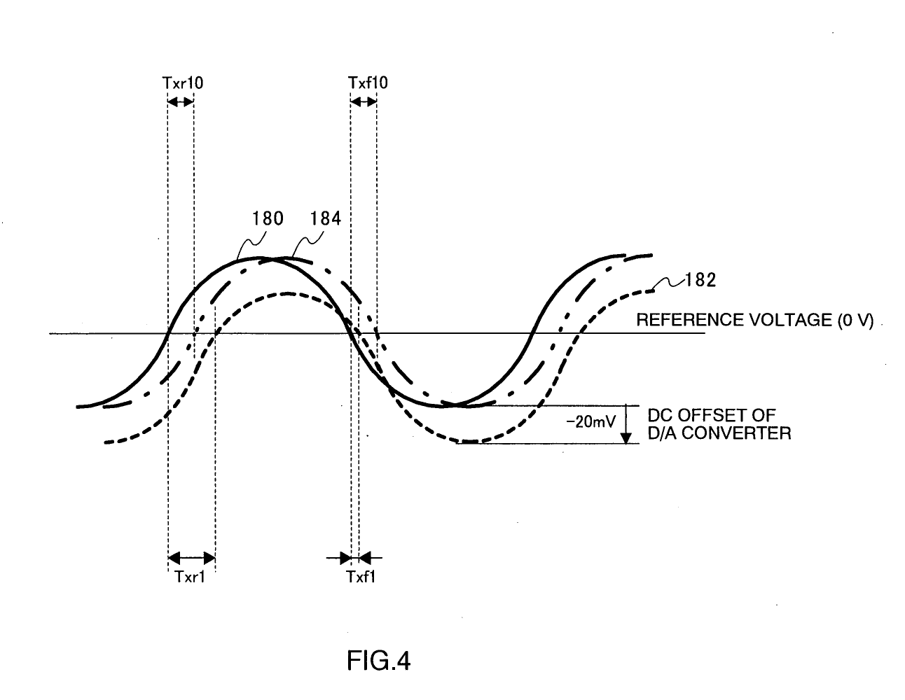

FIG. 1 is a block diagram showing the configuration of a D/A conversion apparatus with an offset compensation function according to Embodiment 1 of the present invention, FIG. 2 and FIG. 3 illustrate the operation thereof and FIG. 4 to FIG. 6 illustrate the reasons that a DC offset of the comparator itself is canceled.

First, the configuration of the D/A conversion apparatus with an offset compensation function according to this embodiment will be explained using FIG. 1.

The D/A conversion apparatus 100 shown in FIG. 1 is provided with an input signal correction section 110, a D/A converter 130 in a differential output configuration, a lowpass filter 140, a comparator 150, an input switchover switch 160 provided before the comparator 150 and a polarity switchover circuit 170 for selectively inverting the polarity of an output signal of the comparator 150. The input switchover switch 160 and polarity switchover circuit 170 are controlled by a mode switchover signal. The lowpass filter 140 may also be incorporated in the D/A converter 130.

The input signal correction section 110 is provided with an MSB extraction circuit 112 that extracts a Most Significant Bit (MSB) from a digital input signal, a decision circuit 114 that carries out predetermined decision processing using the output of the polarity switchover circuit 170 and the output (MSB signal) of the MSB extraction circuit 112, a first integration circuit 116 that integrates the output of the decision circuit 114, a first register 118 that temporarily stores a first zero-cross delay value in a first input mode which will be described later (see FIG. 2), a second register 120 that temporarily stores a second zero-cross delay value in a second input mode which will be described later (see FIG. 3), a calculation/decision circuit 122 that carries out predetermined calculation/decision processing using the first zero-cross delay value and second zero-cross delay value, a second integration circuit 124 that integrates the output of the calculation/decision circuit 122, a third register 126 that stores the output (DC offset compensation value) of the integration circuit 124 and an adder 128 that adds a DC offset compensation value to the digital input signal. The sign of the digital input signal is obtained from the MSB. The two integration circuits 116 and 124 are substantially constructed of up/down counters. This embodiment corrects a digital input signal using a successive approximation scheme using an up/down counter to change the signal value by 1 LSB (Least Significant Bit) at a time. The LSB is minimum resolution of the D/A converter 130.

Therefore, considering that the comparator 150 itself has a DC offset, this D/A conversion apparatus with an offset compensation function 100 corrects a total DC offset with a DC offset between the differential outputs of the D/A converter 130 and DC offset of the comparator 150 itself taken into consideration through negative feedback control.

Next, the operation for compensating for the DC offset will be explained.

This operation is roughly divided into a stage of calculating a first zero-cross delay value (see FIG. 2) in a normal operating mode in which there is a signal to be sent to a radio path and a stage (see FIG. 3) of calculating a second zero-cross delay value, adding up the first and second zero-cross delay values obtained, deciding whether the value is positive, negative or zero, integrating the decision result to thereby calculate a DC offset compensation value and correcting the digital input signal using the DC offset compensation value obtained.

Then, by repeating the above described operation, it is possible to remove the DC offset between the differential outputs of the D/A converter 130.

This will be explained more specifically below.

FIG. 2 shows the operation (procedure) of calculating a first zero-cross delay value in a normal operating mode with bold lines.

First, the count values of the integration circuits 116 and 124 and the values of the registers 118, 120, and 126 are reset to zero. At this time, the given digital input signal is output from the adder 128 as is and given to the D/A converter 130 in the differential output configuration.

Complementary outputs of mutually opposite phases are obtained from the D/A converter 130 and further deprived of unnecessary noise (high-frequency component) by passing through the lowpass filter 140. Here, these two output signals are expressed as “A+” and “A−”. Suppose A+ is an output in phase with the digital input data and A− is an output of opposite phase. The A+ and A− signals are input to the comparator 150 through the input switchover switch 160.

As shown in the figure, the input switchover switch 160 has the function of selectively connecting two input terminals a and b to either an output terminal c or d respectively.

In the input switchover switch 160 shown in FIG. 2, the terminal a is connected to the terminal c and the terminal b is connected to the terminal d. Suppose this state is a first input mode.

In this first input mode, the polarity switchover circuit 170 allows the output signal of the comparator 150 to pass as is.

The output signal {+1, −1} of the comparator 150 and the MSB {+1, −1} of the digital input signal output from the MSB extraction circuit 112 are input to the decision circuit 114. The output signal {+1, 0, −1} of the decision circuit 114 is given to the first integration circuit 116 constructed of an up/down counter. Here, the decision circuit 114 operates according to the following truth table. Here, “+1” means a high level and “−1” means a low level.

TABLE 1

| MSB OF DIGITAL | OUTPUT SIGNAL OF | OUTPUT SIGNAL OF |
|---|---|---|
| INPUT SIGNAL | COMPARATOR | DECISION CIRCUIT |
| −1 | +1 | +1 |
| +1 | +1 | 0 |
| −1 | −1 | 0 |
| +1 | −1 | −1 |

The integration circuit (up/down counter) 116 carries out a downcount when the output signal of the decision circuit 114 given at this time is “+1”, carries out an up count when “−1” and does nothing when “0”.

The count operation of the integration circuit (up/down counter) 116 at this time is carried out for a period including one or a plurality of successive zero-cross delays during a rise time and zero-cross delays during a fall time of the digital input signal and the analog output signal of the D/A converter 130 after passing through the lowpass filter 140.

Furthermore, the clock frequency of the integration circuit (up/down counter) 116 is preferably equal to or greater than a frequency, one cycle of which consists of a variation time of the zero-cross delay value due to a variation by 1 LSB of the analog output signal of the D/A converter 130, but when the clock frequency is lower than that frequency, it is possible to improve the measuring accuracy by carrying out a count operation for a period including a plurality of successive zero-cross delays during a rise time and zero-cross delays during a fall time of the digital input signal and the analog output signal of the D/A converter 130 after passing through the lowpass filter.

After the count operation of the integration circuit (up/down counter) 116 is completed, the count value at this time is stored in the first register 118 as the first zero-cross delay value.

Next, as shown in FIG. 3, the input switchover switch 160 is controlled so as to connect the terminal a to the terminal d and connect the terminal b to the terminal c. Suppose this is a second input mode.

At this time, the polarity switchover circuit 170 inverts the polarity of the output signal of the comparator 150. That is, an inverted output signal of the comparator 150 and the MSB of the digital input signal output from the MSB extraction circuit 112 are input to the decision circuit 114. The output signal of the decision circuit 114 is given to the first integration circuit 116.

In such a state, the count value of the integration circuit (up/down counter) 116 is returned to zero and a count operation similar to that in the first input mode shown in FIG. 2 is carried out. The resulting count value is stored in the second register 120 as the second zero-cross delay value.

Then, the first and second zero-cross delay values are extracted from the register 118 and register 120 respectively and the calculation/decision circuit 122 adds up the first and second zero-cross delay values and decides whether the value is positive, negative or zero. The result of this decision (decision output signal) {+1, 0, −1} is given to the second integration circuit 124 made up of an up/down counter.

The integration circuit (up/down counter) 124 carries out an upcount when the output signal of the calculation/decision circuit 122 is “+1”, carries out a downcount when “−1” and does nothing when “0”. After the count operation is completed, the count value at this time is stored in the third register 126 as the DC offset compensation value.

Then, the DC offset compensation value is extracted from the register 126, the adder 128 adds the DC offset compensation value to the digital input signal to thereby correct the digital input signal.

By repeating the above described operation, it is possible to remove the DC offset between the differential outputs of the D/A converter 130 and the DC offset of the comparator 150 simultaneously and substantially completely.

Here, the reason that the DC offset of the comparator 150 itself is completely masked and disappears using the above described method will be explained more specifically using FIG. 4 to FIG. 6. Here, suppose the minimum resolution (LSB) of the D/A converter 130 is 1 mV.

Since the differential outputs A+, A− of the D/A converter 130 are independent of each other, if there is a DC offset in the D/A converter 130, the DC offset appears as a DC offset between the differential outputs. Here, suppose, of the complementary outputs of the D/A converter 130, the DC offset of A+ is −20 mV and the DC offset of A− is 0 mV.

The two outputs must originally be 0 mV. Therefore, in this case, a DC offset between the differential outputs of −20 mV is produced.

FIG. 4 illustrates waveforms of (A+)-(A−) when there is no DC offset in the comparator 150. In the same figure, a solid line 180 represents a digital input signal, a dotted line 182 represents an analog output of the D/A converter 130 after passing through the lowpass filter 140 when there is a DC offset (−20 mV) in the D/A converter 130, that is, a filter output before an offset correction, and a one-dot dashed line 184 represents an analog output of the D/A converter 130 after passing through the lowpass filter 140 when there is no DC offset in the D/A converter 130, that is, a filter output after an offset correction.

Here, when attention is focused on the zero-cross delay values during a rise time and zero-cross delay values during a fall time of the digital input signal and the analog output signal of the D/A converter 130 after passing through the lowpass filter 140, the circuit in this embodiment is constructed in such a way that the zero-cross delay value during a rise time takes a positive count value when the DC offset is in the vicinity of zero and the zero-cross delay value during a fall time takes a negative count value, and therefore the sum of the zero-cross delay value during a rise time and the zero-cross delay value during a fall time is substantially proportional to the DC offset of the D/A converter 130.

Therefore, by measuring the sum of the zero-cross delay value during a rise time and the zero-cross delay value during a fall time, it is possible to roughly estimate the DC offset of the D/A converter 130.

That is, when there is no DC offset in the D/A converter 130, adding up the zero-cross delay value (Txr10) during a rise time and the zero-cross delay value (Txf10) during a fall time causes the count value to become zero.

On the other hand, when there is a DC offset (−20 mV) in the D/A converter 130, adding up the zero-cross delay values (Txr1) during a rise time and the zero-cross delay value (Txf1) during a fall time causes the count value to become a positive count value.

Furthermore, even when the input switchover switch 160 is switched over by a mode switchover signal, the DC offset of the comparator 150 becomes zero, and therefore the registers 118 and 120 have the same positive value.

Therefore, the integration circuit 124 is counted up by 1 from an initial value and the count value is stored in the register 126. The adder 128 adds the value of the register 126 to the digital input signal and the digital input signal is thereby corrected.

Repeating the above described operation causes the DC offset of the D/A converter 130 to be corrected finally.

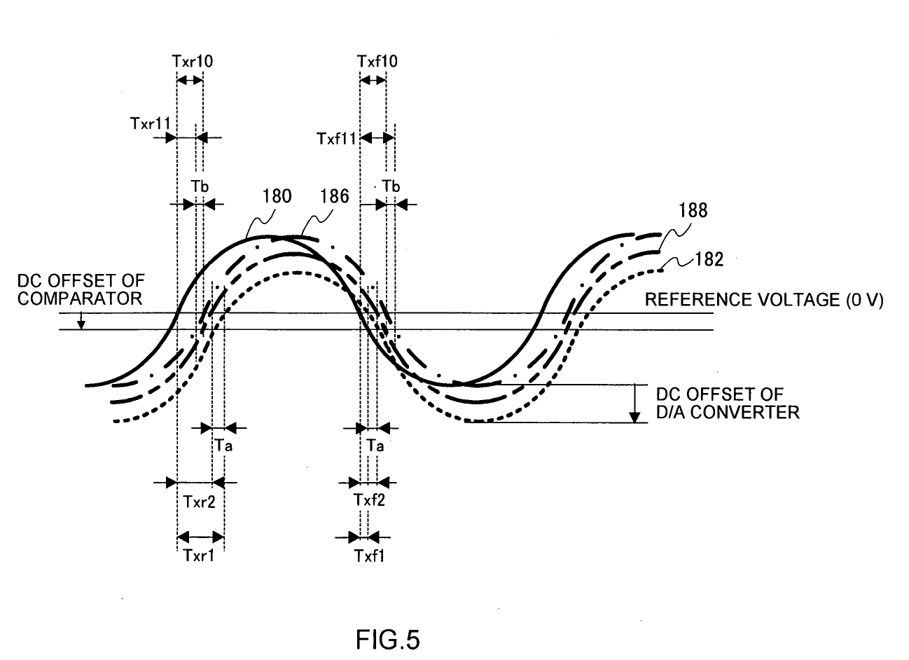

FIG. 5 illustrates waveforms of (A+)-(A−) when there is a DC offset in the comparator 150 and in a first switch state (first input mode). As in the case of FIG. 4, a solid line 180 represents a digital input signal, a dotted line 182 represents an analog output of the D/A converter 130 after passing through the lowpass filter 140 when there is a DC offset (−20 mV) in the D/A converter 130 (that is, filter output before offset correction), a one-dot dashed line 186 represents the analog output of the D/A converter 130 after passing through the lowpass filter 140 in an ideal state in which there is no DC offset in either D/A converter 130 or comparator 150 (that is, ideal filter output) and a two-dot dashed line 188 represents the analog output of the D/A converter 130 after passing through the lowpass filter 140 when there is no DC offset in the D/A converter 130, that is, a convergent waveform of the filter output after offset correction.

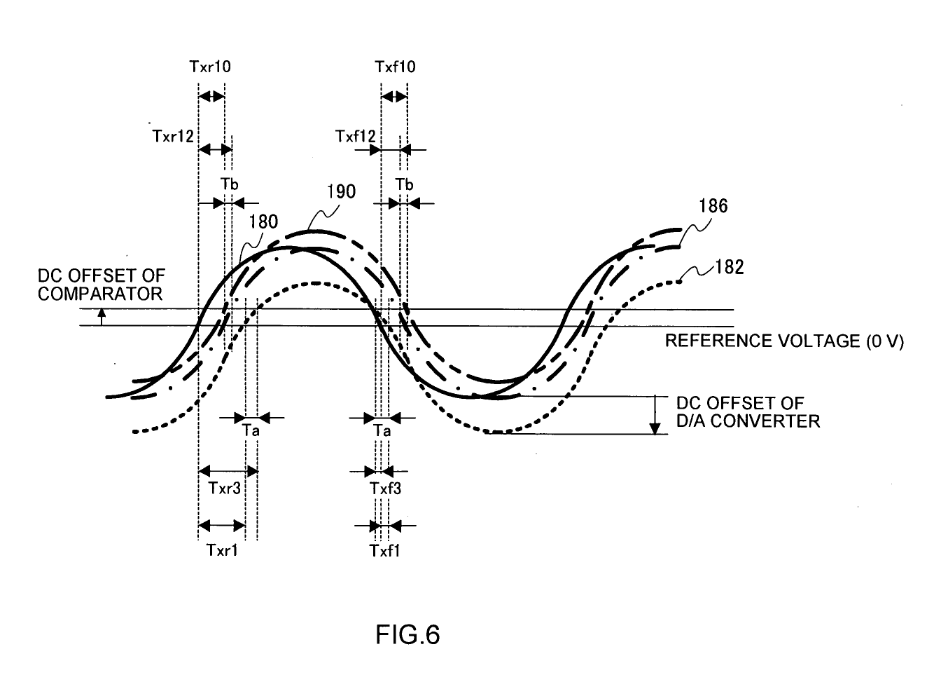

Furthermore, FIG. 6 illustrates waveforms of (A+)-(A−) when there is a DC offset in the comparator 150 and in a second switch state (second input mode). As in the case of FIG. 5, a solid line 180 represents a digital input signal, a dotted line 182 represents an analog output of the D/A converter 130 after passing through the lowpass filter 140 when there is a DC offset (−20 mV) in the D/A converter 130 (that is, filter output before offset correction), a one-dot dashed line 186 represents the analog output of the D/A converter 130 after passing through the lowpass filter 140 in an ideal state in which there is no DC offset in either the D/A converter 130 or comparator 150 (that is, ideal filter output) and a two-dot dashed line 190 represents the analog output of the D/A converter 130 after passing through the lowpass filter 140 when there is no DC offset in the D/A converter 130, that is, a convergent waveform of the filter output after offset correction.

Here, the zero-cross delay value when there is a DC offset in the comparator 150 and the DC offset of the D/A converter 130 is −20 mV, that is, at the start of offset correction will be observed.

In the case of the first switch state in FIG. 5, the zero-cross delay value (Txr2) during a rise time is smaller than Txr1 in FIG. 4 when there is no DC offset in the comparator 150 by a delay value (Ta) due to the DC offset of the comparator 150. That is, Txr2=Txr1−Ta. Furthermore, the zero-cross delay value (Txf2) during a fall time is also smaller than Txf1 in FIG. 4 by Ta. That is, Txf2=Txf1−Ta. Therefore, the first zero-cross delay value (Txr2+Txf2) becomes Txr1+Txf1−2Ta.

On the other hand, in the case of the second switch state in FIG. 6, the zero-cross delay value (Txr3) during a rise time is greater than Txr1 in FIG. 4 when there is no DC offset in the comparator 150 by the delay value (Ta) due to the DC offset of the comparator 150. That is, Txr3=Txr1+Ta. Furthermore, the zero-cross delay value (Txf3) during a fall time is also greater than Txf1 in FIG. 4 by Ta. That is, Txf3=Txf1+Ta. Therefore, the second zero-cross delay value (Txr3+Txf3) is Txr1+Txf1+2Ta.

Adding up the first zero-cross delay value (Txr2+Txf2) and the second zero-cross delay value (Txr3+Txf3) results in:

$$\begin{matrix}( Txr 2 + Txf 2 ) + ( Txr 3 + Txf 3 ) = ( Txr 1 + Txf 1 - 2 Ta ) + \\ ( Txr 1 + Txf 1 + 2 Ta ) \\ = 2 ( Txr 1 + Txf 1 )\end{matrix}$$

That is, the sum of the first zero-cross delay value (Txr2+Txf2) and the second zero-cross delay value (Txr3+Txf3) becomes equal to twice the zero-cross delay value (Txr1+Txf1) when there is no DC offset in the comparator 150 and the delay value due to the DC offset of the comparator 150 is canceled.

Next, the zero-cross delay value when the DC offset of the comparator 150 and the DC offset of the D/A converter 130 are corrected will be observed.

In the case of the first switch state in FIG. 5, the zero-cross delay value (Txr11) during a rise time is smaller than Txr10 in FIG. 4 when there is no DC offset in the comparator 150 by the delay value (Tb) due to the DC offset of the comparator 150. That is, Txr11=Txr10−Tb. Furthermore, the zero-cross delay value (Txf11) during a fall time is also smaller than Txf10 in FIG. 4 by Tb. That is, Txf11=Txf10−Tb. Therefore, the first zero-cross delay value (Txr11+Txf11) is Txr10+Txf10−2Tb.

On the other hand, in the case of the second switch state in FIG. 6, the zero-cross delay value (Txr12) during a rise time is greater than Txr10 in FIG. 4 when there is no DC offset in the comparator 150 by the delay value (Tb) due to the DC offset of the comparator 150. That is, Txr12=Txr10+Tb. Furthermore, the zero-cross delay value (Txf12) during a fall time is also greater than Txf10 in FIG. 4 by Tb. That is, Txf12=Txf10+Tb. Therefore, the second zero-cross delay value (Txr12+Txf12) is Txr10+Txf10+2Tb.

Then, adding up the first zero-cross delay value (Txr11+Txf11) and the second zero-cross delay value (Txr12+Txf12) results in:

$$\begin{matrix}( Txr 11 + Txf 11 ) + ( Txr 12 + Txf 12 ) = ( Txr 10 + Txf 10 - 2 Tb ) + \\ ( Txr 10 + Txf 10 + 2 Tb ) \\ = 2 ( Txr 10 + Txf 10 )\end{matrix}$$

That is, the sum of the first zero-cross delay value (Txr11+Txf11) and the second zero-cross delay value (Txr12+Txf12) becomes equal to twice the zero-cross delay value (Txr10+Txf10) when there is no DC offset in the comparator 150 and the delay value due to the DC offset of the comparator 150 is canceled.

Thus, by repeating a series of operations of switching the input switchover switch 160, measuring the first zero-cross delay value and the second zero-cross delay value, adding up the two zero-cross delay values obtained, deciding whether the value is positive, negative or zero, integrating the result, thereby generating a DC offset compensation value, adding the DC offset compensation value to the digital input signal through the adder 128 and correcting the value, this embodiment can remove the DC offset between the differential outputs of the D/A converter 130 substantially completely without being affected by the DC offset of the comparator 150.

In this embodiment, when the operations of the polarity switchover circuit 170 in the first input mode and second input mode are reversed, the operation of the decision circuit 114 can be changed so that their decision outputs become the same.

Moreover, when +1 and −1 are switched over in the decision outputs of the decision circuit 114, the operations of count up and count down of the up/down counter of the integration circuit 116 can be reversed.

Furthermore, when the operations of count up and count down of the up/down counter of the integration circuit 116 are reversed, the polarity of the first zero-cross delay value of the register 118 and the polarity of the second zero-cross delay value of the register 120 are switched over, and therefore the operation of the calculation/decision circuit 122 can be changed so that the influence of the delay value due to the DC offset of the comparator 150 is canceled out.

Furthermore, when +1 and −1 are switched over in the decision outputs of the calculation/decision circuit 122, the operations of count up and count down of the up/down counter of the integration circuit 124 can be reversed.

Furthermore, when the operations of count up and count down of the up/down counter of the integration circuit 124 are reversed, the polarity of the DC offset compensation value of the register 126 is switched, and therefore it is possible to select either the adder 128 or a subtractor according to the polarity.

### Embodiment 2

While Embodiment 1 describes the case where the present invention is used to compensate for an offset of the differential output type D/A converter, Embodiment 2 describes a case where the present invention is used to compensate for an offset of a single output type D/A converter.

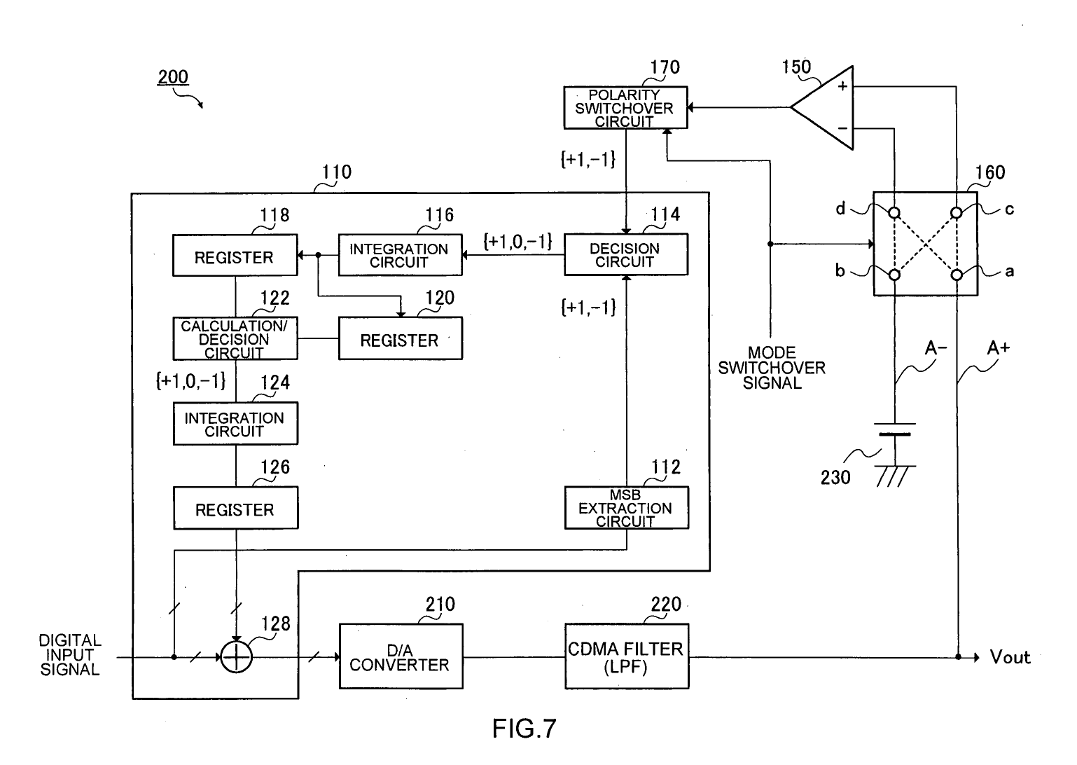

FIG. 7 is a block diagram showing the configuration of a D/A conversion apparatus with an offset compensation function according to Embodiment 2 of the present invention. This D/A conversion apparatus 200 has a basic configuration similar to that of the D/A conversion apparatus 100 shown in FIG. 1 and the same components are assigned the same reference numerals and explanations thereof will be omitted.

A feature of this embodiment is to use a single output type D/A converter 210 instead of the differential output type D/A converter 130 in Embodiment 1. The output of the D/A converter 210 is deprived of unnecessary noise (high-frequency component) through a CDMA filter (lowpass filter: LPF) 220. In this case, one input (A+) of an input switchover switch 160 is the output signal of the D/A converter 210 after passing through the CDMA filter 220 and the other input (A−) is a reference voltage. The reference voltage is equivalent to, for example, an output voltage of an ideal D/A converter and is given by a power supply 230 here. The CDMA filter 220 may also be incorporated in the D/A converter 210.

In this embodiment, the operations of measuring a DC offset and correcting a digital input signal are completely the same as the operations explained using FIG. 4 to FIG. 6 in Embodiment 1. However, the reference voltage used in this embodiment need not always be a voltage equivalent to the output of the ideal D/A converter, but can be at least a constant voltage value.

As also explained in Embodiment 1, in this embodiment, when the operations of a polarity switchover circuit 170 in a first input mode and second input mode are reversed, the operation of a decision circuit 114 can be changed so that their decision outputs become the same. Furthermore, when +1 and −1 are switched over in the decision outputs of the decision circuit 114, the operations of count up and count down of an up/down counter of an integration circuit 116 may be reversed. Furthermore, when the operations of count up and count down of the up/down counter of the integration circuit 116 are reversed, the polarity of a first zero-cross delay value of a register 118 and the polarity of a second zero-cross delay value of a register 120 are switched over, and therefore the operation of a calculation/decision circuit 122 can be changed so that the influence of the delay value due to a DC offset of a comparator 150 is canceled out. Furthermore, when +1 and −1 in the decision outputs of the calculation/decision circuit 122 are switched over, the operations of count up and count down of an up/down counter of an integration circuit 124 can be reversed. Furthermore, when the operations of count up and count down of the up/down counter of the integration circuit 124 are reversed, the polarity of a DC offset compensation value of a register 126 is switched, and therefore it is possible to select either an adder 128 or a subtractor according to the polarity.

### Embodiment 3

While Embodiment 1 corrects a digital input signal using a successive approximation scheme whereby the digital input signal is changed by 1 LSB at a time, Embodiment 3 describes a case where a digital input signal is corrected once for all using a direct correction scheme.

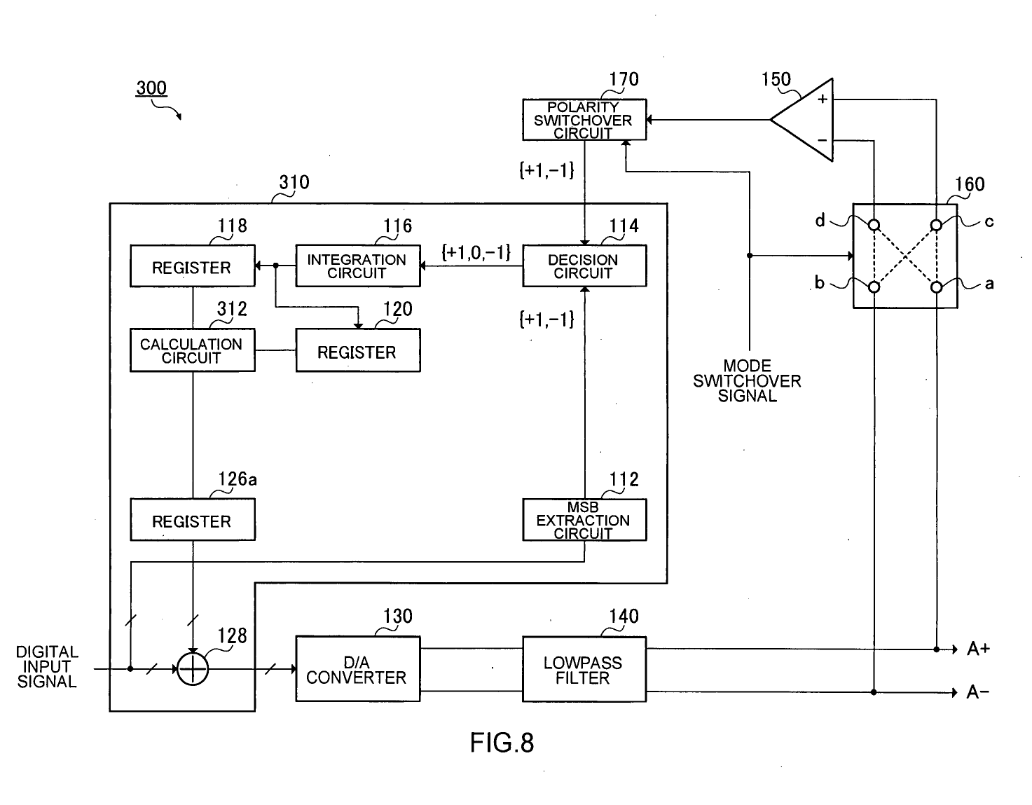

FIG. 8 is a block diagram showing the configuration of a D/A conversion apparatus with an offset compensation function according to Embodiment 3 of the present invention. This D/A conversion apparatus 300 has a basic configuration similar to that of the D/A conversion apparatus 100 shown in FIG. 1 and the same components are assigned the same reference numerals and explanations thereof will be omitted.

A feature of this embodiment is to include an input signal correction section 310 which corresponds to the input signal correction section 110 of Embodiment 1, part of which is changed. In this embodiment, the configuration in which a first zero-cross delay value is stored in a register 118 and a second zero-cross delay value is stored in a register 120 is the same as that of Embodiment 1, but this embodiment is different in the method of creating contents of a register 126a from contents of the two registers 118, 120.

That is, while Embodiment 1 uses a scheme where a digital input signal is corrected using successive approximation based on a value obtained by adding up the first zero-cross delay value and second zero-cross delay value, in this embodiment, a calculation circuit 312 calculates a mean value of the first zero-cross delay value and the second zero-cross delay value and stores the mean value obtained as a DC offset compensation value in the register 126a. Then, this embodiment uses a scheme of extracting a DC offset compensation value from the register 126a, adding the DC offset compensation value to the digital input signal through an adder 128 and correcting the digital input signal once for all.

Therefore, according to this embodiment, it is possible to improve responsivity with respect to a variation of the DC offset.

In order to secure the accuracy of correction, it is preferable to improve the measuring accuracy by carrying out a count operation for a period including a plurality of successive zero-cross delays during a rise time and zero-cross delays during a fall time of the digital input signal and the analog output signal of a D/A converter 130 after passing through a lowpass filter 140.

### Embodiment 4

Embodiment 4 is a case where Embodiment 3 which carries out offset compensation of a differential output type D/A converter is changed so as to carry out offset compensation of a single output type D/A converter.

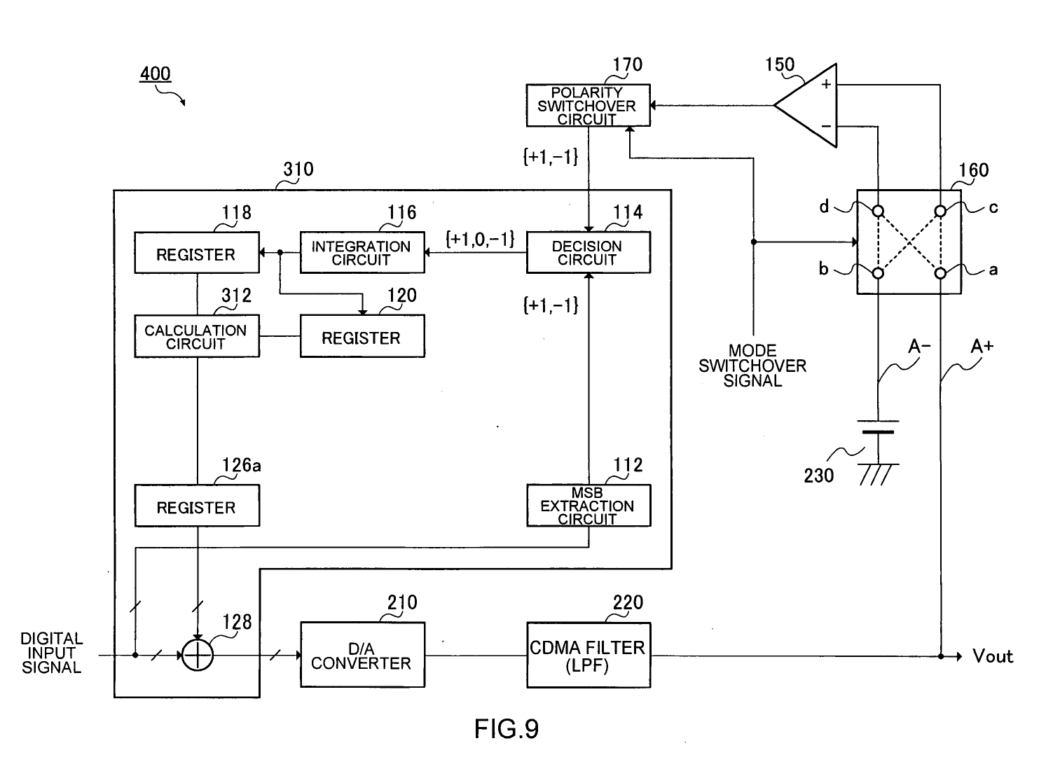

FIG. 9 is a block diagram showing the configuration of a D/A conversion apparatus with an offset compensation function according to Embodiment 4 of the present invention. This D/A conversion apparatus 400 has a basic configuration similar to that of the D/A conversion apparatuses 200, 300 shown in FIG. 2 and FIG. 3 and the same components are assigned the same reference numerals and explanations thereof will be omitted.

A feature of this embodiment is to use a single output type D/A converter 210 instead of the differential output type D/A converter 130 in Embodiment 3. As in the case of Embodiment 2, the output of the D/A converter 210 is deprived of unnecessary noise (high-frequency component) through a CDMA filter (lowpass filter: LPF) 220. In this case, one input (A+) of an input switchover switch 160 is the output signal of the D/A converter 210 after passing through the CDMA filter 220 and the other input (A−) is a reference voltage (equivalent to, for example, the output voltage of an ideal D/A converter). The reference voltage is given by a power supply 230.

### Embodiment 5

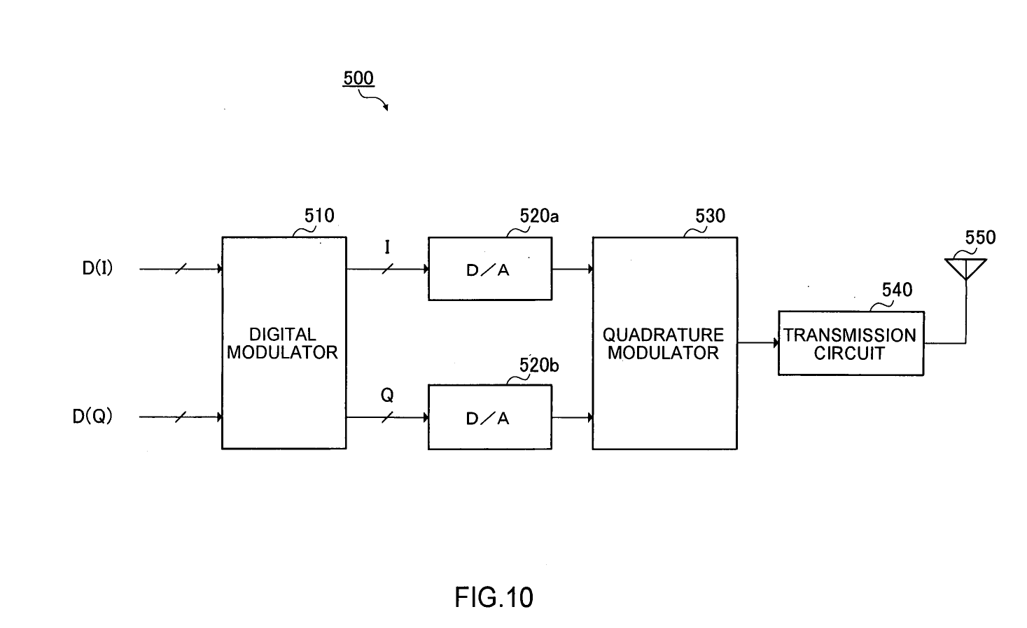

FIG. 10 is a block diagram showing an example of the configuration of a digital radio transmitter provided with the D/A conversion apparatus with an offset compensation function of the present invention.

The digital radio transmitter 500 shown in FIG. 10 is provided with a digital modulator 510, D/A conversion apparatuses (D/A conversion apparatuses with an offset compensation function of the present invention) 520a, 520b corresponding to I and Q respectively, a quadrature modulator 530, a transmission circuit 540 and an antenna 550. The digital modulator 510 is, for example, a spreading modulator. Furthermore, the quadrature modulator 530 is, for example, a QPSK modulator.

For example, the digital modulator 510, D/A conversion apparatuses 520a, 520b and quadrature modulator 530 and transmission circuit 540 are integrated into one LSI.

This embodiment uses D/A conversion apparatuses with an offset compensation function 100 to 400 of the present invention as the D/A conversion apparatuses 520a, 520b, and therefore a DC offset is canceled and the input/output characteristics of the two D/A conversion apparatuses 520a, 520b match and the phases of I, Q transmission signals match. Therefore, it is possible to realize accurate transmission.

As shown above, even when there is a DC offset in a comparator, the present invention can remove a DC offset of a D/A converter substantially completely.

The present invention has the effect of being able to remove the DC offset of the D/A converter even when a DC offset exists in the comparator, and can be used not only for communications but also for audio instruments, etc. That is, the present invention is suitable for use in not only an apparatus for compensating a DC offset of a D/A converter incorporated in a digital radio communication instrument but also an apparatus for compensating a DC offset of a D/A converter incorporated in audio equipment, etc.

The present invention is not limited to the above described embodiments, and various variations and modifications may be possible without departing from the scope of the present invention.

This application is based on the Japanese Patent Application No. 2004-203794 filed on Jul. 9, 2004, entire content of which is expressly incorporated by reference herein.

What is claimed is:

1. A D/A conversion apparatus with an offset compensation function that compensates for a DC offset of a D/A converter, comprising:
a comparator provided with two input terminals that inputs an output signal of said D/A converter to at least one of said input terminals;
a switchover section that switches between a pair of signals which are input to said comparator during a normal operation of transmitting a transmission signal, at least one of which is an output signal of said D/A converter;
a zero-cross delay value generation section that measures and adds up zero-cross delay values during a rise time and during a fall time of the output signals of said D/A converter before and after switching between the pair of signals to be input to said comparator respectively to thereby generate a first zero-cross delay value before switching between the pair of signals to be input to said comparator and a second zero-cross delay value after switching between the pair of signals to be input to said comparator;
a compensation value generation section that generates a compensation value of said DC offset using said first zero-cross delay value and said second zero-cross delay value; and
a correction section that corrects a digital input signal to said D/A converter using said compensation value.

2. The D/A conversion apparatus with an offset compensation function according to claim 1, wherein said D/A converter is of a differential output type that outputs two lines of analog signals having opposite phases, and
said two lines of analog signals of said D/A converter are input to said comparator through said switchover section.

3. The D/A conversion apparatus with an offset compensation function according to claim 1, wherein said D/A converter is of a single output type that outputs only one line of analog signals having the same phase, and
said one line of analog signals of said D/A converter and a predetermined reference voltage are input to said comparator through said switchover section.

4. The D/A conversion apparatus with an offset compensation function according to claim 1, wherein said compensation value generation section generates a compensation value of said DC offset through successive approximation using said first zero-cross delay value and said second zero-cross delay value.

5. The D/A conversion apparatus with an offset compensation function according to claim 4, wherein said compensation value generation section adds up said first zero-cross delay value and said second zero-cross delay value, decides the sign of the addition result and integrates the decision result to thereby generate a compensation value of said DC offset.

6. The D/A conversion apparatus with an offset compensation function according to claim 1, wherein said compensation value generation section calculates a mean value of said first zero-cross delay value and said second zero-cross delay value to thereby generate a compensation value of said DC offset.

7. The D/A conversion apparatus with an offset compensation function according to claim 1, wherein said zero-cross delay value is measured for a period including one zero-cross delay during a rise time and one zero-cross delay during a fall time of the digital input signal and the output signal of said D/A converter.

8. The D/A conversion apparatus with an offset compensation function according to claim 1, wherein said zero-cross delay value is measured for a period including a plurality of successive zero-cross delays during a rise time and zero-cross delays during a fall time of the digital input signal and the output signal of said D/A converter.

9. An offset compensation method for a D/A conversion apparatus for inputting an output signal of a D/A converter to at least one input terminal of a comparator and compensating for a DC offset of said D/A converter using the output signal of said comparator, comprising the steps of:
switching between a pair of signals which are input to said comparator during a normal operation of transmitting a transmission signal and at least one of which is an output signal of said D/A converter;
measuring zero-cross delay values during a rise time and during a fall time of the output signals of said D/A converter before and after switching between the pair of signals input to said comparator and adding up the zero-cross delay values to thereby generate a first zero-cross delay value before switching between the pair of signals to be input to said comparator and a second zero-cross delay value after switching between the pair of signals to be input to said comparator;
generating a compensation value of said DC offset using said first zero-cross delay value and said second zero-cross delay value; and
correcting a digital input signal to said D/A converter using said compensation value.
